(19) United States
(12) Patent Application Publication
(10) Pub. No.: US 2012/0224804 A1
(43) Pub. Date: Sep. 6, 2012

(54) SEMICONDUCTOR DEVICE AND METHOD OF MANUFACTURING THE SAME

(76) Inventors: Yoshihito Hashimoto, Tokyo (JP); Yoichi Hashimoto, Tokyo (JP)

(21) Appl. No.: 13/505,726

(22) PCT Filed: Oct. 25, 2010
(86) PCT No.: PCT/JP2010/006302

§ 371 Date: May 2, 2012

(30) Foreign Application Priority Data
Nov. 4, 2009 (JP) 2009-253117

(51) Int. Cl. G02B 6/12; H01L 21/50

(52) U.S. Cl. 385/14; 438/27; 257/E21.499

(57) ABSTRACT

A semiconductor device (and method thereof) includes an LSI chip, a package substrate, an optical element chip, and a flexible optical waveguide substrate. The LSI chip and the optical element chip are mounted on an upper surface of the package substrate. The optical element chip is electrically connected to the LSI chip through the package substrate. One end of the flexible optical waveguide substrate is optically coupled to the optical element chip, and the other end is arranged on a bottom surface side of the package substrate.

### TECHNICAL FIELD

The present invention relates to a semiconductor device and a method of manufacturing the same, and more particularly, to a semiconductor device and a method of manufacturing the same for performing input and output by optical signals.

### BACKGROUND ART

With the spread of the Internet, the amount of information handled by equipment such as servers and routers has been dramatically increasing. Accordingly, transmission capacity of signals transmitted and received among semiconductor elements including large scale integrations (LSIs) or the like forming such equipment is predicted to continue a rapid increase for the future. In view of such circumstances, high-speed operation and high capacity of signal transmission among semiconductor elements including LSIs or the like have been the main issues.

Typically, semiconductor elements including LSIs are interconnected by electrical lines. This allows transmission of electrical signals among LSIs or the like through the electrical lines. However, typical electrical signal transmission includes the following problems in order to deal with high-speed operation and high capacity of signals transmitted and received among LSIs or the like.

An increase in frequency causes an increase in signal loss in transmission of electrical signals through electrical lines. Thus, higher transmission rate of signals prompts degradation of waveforms of signals, which increases probability of a transmission error. The signal waveforms that are degraded may be restored to some degree with the use of a waveform shaping circuit or the like. However, an increase in transmission rate of signals causes not only difficulty in using the waveform shaping circuit itself, but also an increase in power consumed by the waveform shaping circuit.

Further, an increase in frequency causes an increase in crosstalk between electrical lines. Accordingly, high transmission rate of signals causes degradation of signal waveforms due to crosstalk. It is required to increase wiring intervals or to provide a shield between lines in order to reduce crosstalk. Thus, the packaging density of lines decreases, which leads to an increase in size of the device. Further, since the electrical signal is susceptible to the influence of electromagnetic noise, a shield or the like is required to reduce the influence of the electromagnetic noise. This also leads to reduction in packaging density of lines, which leads to the increase in size of the device as well.

As one method to solve the problems in such electrical signal transmission, there are high expectations for a technique of optical interconnection to connect semiconductor elements including LSIs or the like by optical lines to achieve transmission of optical signals through optical lines. The optical lines have the following advantages compared to the electrical lines.

First, high frequency loss in the optical lines is negligibly small compared to that of electrical lines. Thus, signal degradation is negligibly small even when high-speed and high-capacity optical signals are transmitted. Accordingly, a waveform shaping circuit is not necessary.

Further, there is no crosstalk in the optical lines, which eliminates the need to take wide gaps in the optical lines, and the shield between optical lines is not necessary as well. Furthermore, the optical lines are not susceptible to the influence of electromagnetic noise, which also eliminates the need to provide a shield against noise.

Accordingly, by taking such advantages using the optical interconnection, it is possible to achieve high-speed and high-capacity signal transmission among future LSIs or the like with high density and low power.

The optical interconnection requires an optical interface that performs interconversion of the electrical signal and the optical signal. Typically, the optical interface includes an optical element, and a drive circuit for driving the optical element. The optical element here includes a laser diode which is a light emitting element or a photodiode which is a light receiving element. Further, the drive circuit includes a driver or a receiver driving the optical element. By electrically connecting the optical interface and the LSI or the like, the electrical signal output from the LSI or the like may be converted into an optical signal to be output, or the optical signal input from outside may be converted into an electrical signal to input the electrical signal to the LSI or the like. Note that the optical input and output signals of the optical interface are typically transmitted using optical lines including an optical waveguide and an optical fiber.

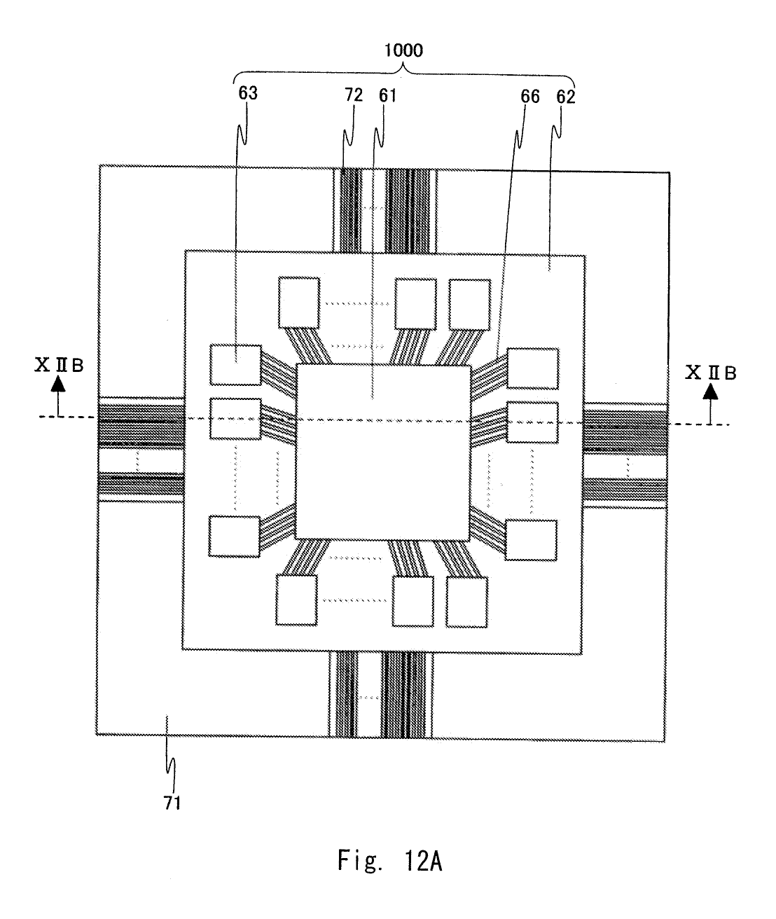

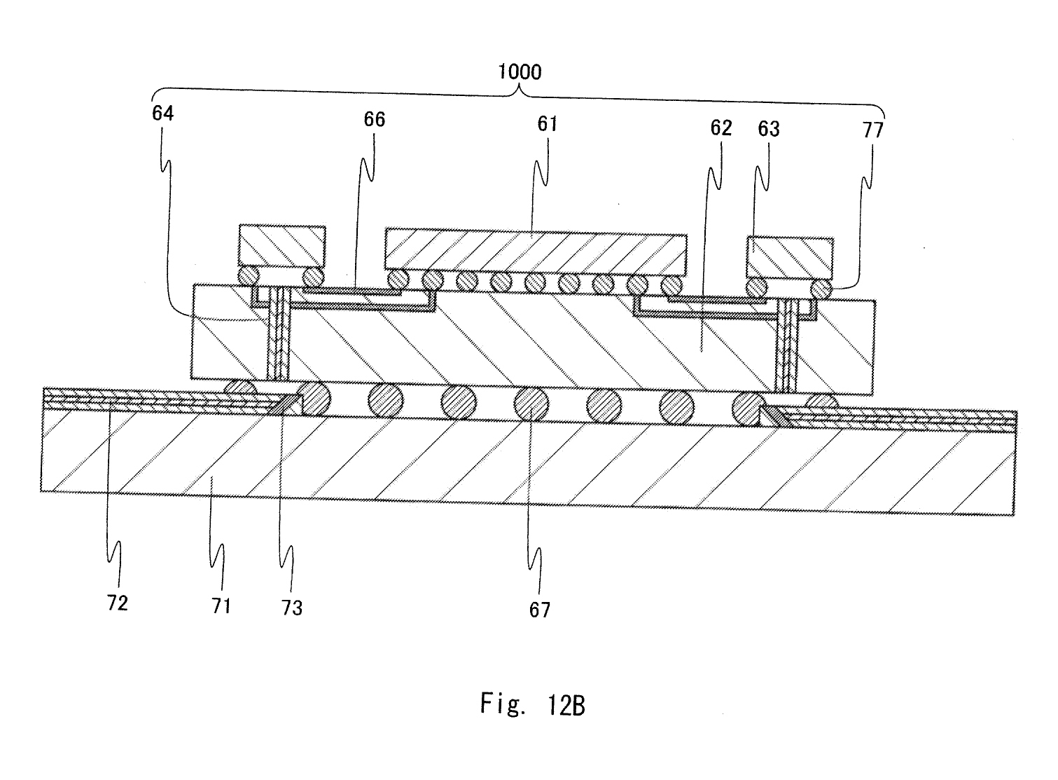

One method of mounting an optical interface on a package substrate of an LSI package has been proposed as an aspect for mounting an optical interface for achieving high-speed and high-capacity optical interconnection of future LSIs or the like (a non-patent literature 1, a patent literature 1). Such a structure achieves a semiconductor package having optical input and output. In the following description, with reference to the drawings, a structure of an LSI package having typical optical input and output will be described. FIG. 12A is a top view showing a structure of an LSI package 1000 having optical input and output. Further, FIG. 12B is a cross sectional view of the LSI package 1000 taken along the line XIIB-XIIB of FIG. 12A. First, a planar structure of the LSI package 1000 will be described. As shown in FIG. 12A, an LSI chip 61 and an optical element chip 63 are arranged above a package substrate 62. In the LSI package 1000, the LSI chip 61 and the optical element chip 63 are electrically and mechanically connected to an electrical line 66 of the package substrate 62 by flip-chip connection or the like. In this way, the LSI chip 61 and the optical element chip 63 are electrically connected through the electrical line 66. The LSI package 1000 is mounted on a board 71. A plurality of optical waveguides 72 are formed in the board 71.

Subsequently, a cross sectional structure of the LSI package 1000 will be described. As shown in FIG. 12B, the LSI chip 61 and the optical element chip 63 are mounted on the package substrate 62 with bumps 77 interposed therebetween. The LSI chip 61 and the optical element chip 63 are electrically connected through the electrical line 66. Optical vias 64 are formed in the package substrate 62 immediately below the optical element chip 63.

Solder balls 67 are arranged in the bottom surface of the package substrate 62. The solder balls 67 are electrically connected to the LSI chip 61, and are used to supply power or for ground (GND) connection, for example. The package substrate 62 is electrically and mechanically connected to the board 71 through the solder balls 67, and is used to supply power and for ground (GND) connection, for example. An electrical line (not shown) and an optical waveguide 72 are formed in the board 71. A mirror 73 is formed at an end of the optical waveguide 72.

An electrical signal output from the LSI chip 61 is input to the optical element chip 63 through the electrical line 66. This electrical signal is converted into an optical signal, which is output from the optical element chip 63. The optical signal output from the optical element chip 63 propagates to a bottom surface side of the package substrate 62 through the optical vias 64 formed in the package substrate 62. Then, the optical signal is input to the optical waveguide 72 of the board 71, and propagates after its path is changed by the mirror 73 formed in the optical waveguide 72. On the other hand, the optical signal propagating the optical waveguide 72 of the board 71 is input to the optical vias 64 after its path is changed by the mirror 73. Then, the optical signal propagates to the upper surface side of the package substrate 62 through the optical vias 64, and is input to the optical element chip 63. The optical signal input to the optical element chip 63 is converted into an electrical signal, which is output from the optical element chip 63. The electrical signal that is output is input to the LSI chip 61 through the electrical line 66. Accordingly, the use of the LSI package 1000 achieves transmission and reception of optical signals through the optical waveguides of the board among LSIs mounted on separate packages.

Note that, in the semiconductor device having optical input and output like the LSI package 1000, the important problem is how to optically couple the optical waveguides and the optical elements formed in the optical element chip efficiently. To deal with this problem, a method using optical vias (e.g., non-patent literature 1) and a method using optical pins (e.g., patent literature 1) have been proposed. The LSI package 1000 shown in FIGS. 12A and 12B uses optical vias. Both methods achieve optical coupling of the optical waveguides formed in the board and the optical elements formed in the optical element chip by providing a light path penetrating the package substrate in the vertical direction (e.g., optical vias or optical pins).

### CITATION LIST

### Patent Literature

PTL 1: Japanese Unexamined Patent Application Publication No. 2006-10927

### Non Patent Literature

NPL 1: K. Oda, and four others, “Optical Connection between Optical Via Hole in BGA Package and Optical Waveguide on Board”, IEICE Trans. Electron., 2009, VOL. E92-C, NO. 2, pp. 239-246

### SUMMARY OF INVENTION

### Technical Problem

However, the LSI package according to the aforementioned structure causes the following problems. Such an LSI package necessitates optical vias or optical pins penetrating the package substrate. The optical vias or the optical pins are formed or arranged in holes created on the package substrate using a tool such as a drill. Accordingly, the positional accuracy is limited by machine accuracy, thereby unable to achieve positional accuracy required for optical elements. Thus, mis-alignment between the optical elements and optical vias or the like is large, and the efficiency of optical coupling is low.

Further, the optical vias and the optical pins each have a straight shape, which means the positions of optical coupling between the optical vias or the optical pins and the optical waveguides of the board are immediately below the optical elements. Thus, the optical coupling area between the optical vias or the optical pins and the optical waveguides of the board spreads to a wide range. Accordingly, this area is susceptible to the influence of mis-alignment caused by warpage by heat or stress of a board or a package substrate, which degrades optical coupling efficiency.

Furthermore, large space is occupied by the optical waveguides of the board, which makes it difficult to improve packaging density of the optical lines on the board. Accordingly, there is a limitation in reducing size of the LSI package.

The present invention has been made in view of the above circumstances, and aims to provide a semiconductor device and a method of manufacturing the same which achieve input and output of optical signals with excellent optical coupling efficiency.

### Solution to Problem

A semiconductor device according to one exemplary aspect of the present invention includes: a semiconductor integrated circuit; a package substrate on which the semiconductor integrated circuit is mounted; an optical element that is arranged on a first surface of the package substrate and electrically connected to the semiconductor integrated circuit through the package substrate; and a flexible optical waveguide that has one end optically coupled to the optical element and another end arranged on a side of a second surface of the package substrate opposed to the first surface, the flexible optical waveguide having flexibility.

A method of manufacturing a semiconductor device according to another exemplary aspect of the present invention includes: mounting a semiconductor integrated circuit on a package substrate; arranging an optical element on a first surface of the package substrate to electrically connect the optical element to the semiconductor integrated circuit through the package substrate; and optically coupling the optical element and one end of a flexible optical waveguide having flexibility, and arranging another end of the flexible optical waveguide on a side of a second surface of the package substrate opposed to the first surface.

### Advantageous Effects of Invention

According to the present invention, it is possible to provide a semiconductor device and a method of manufacturing the same which achieve input and output of optical signals with excellent optical coupling efficiency.

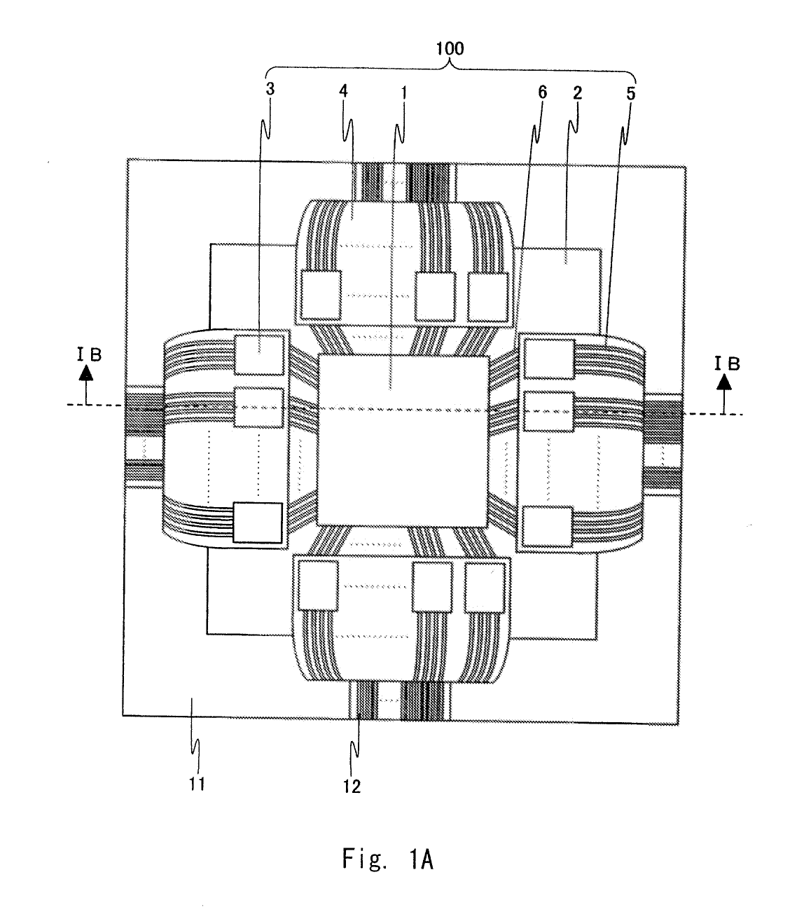

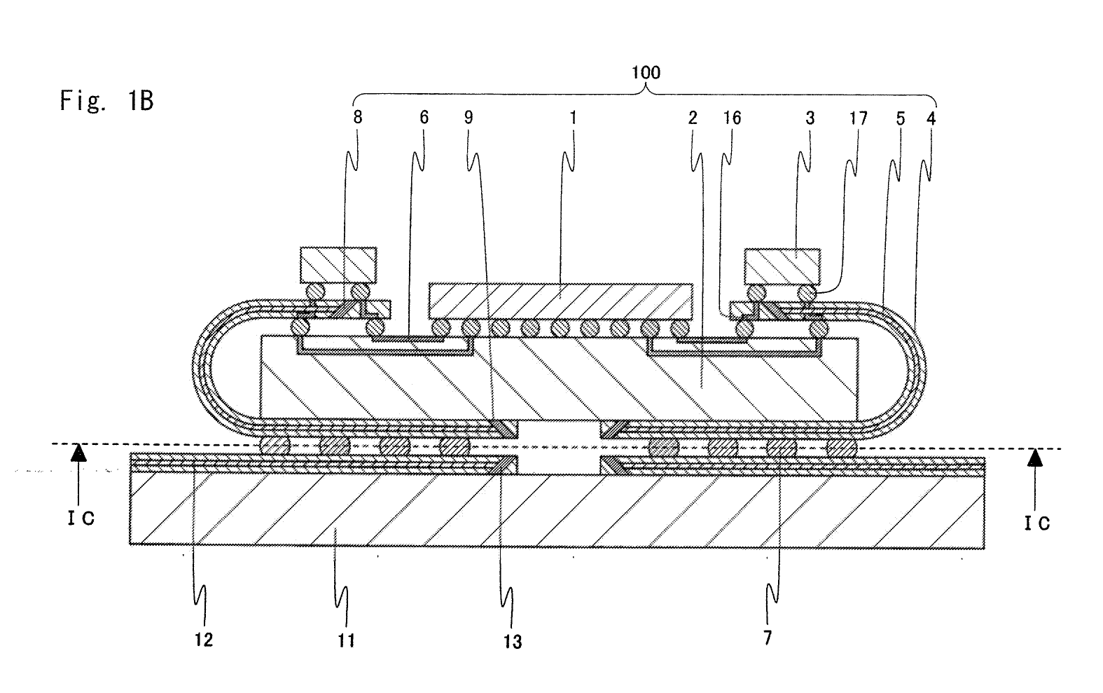

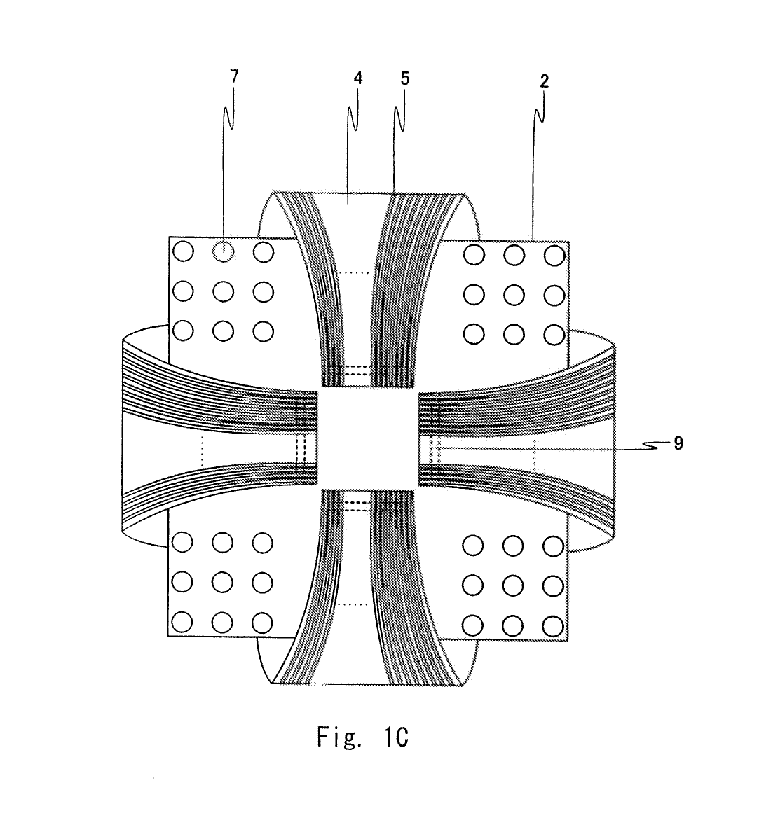

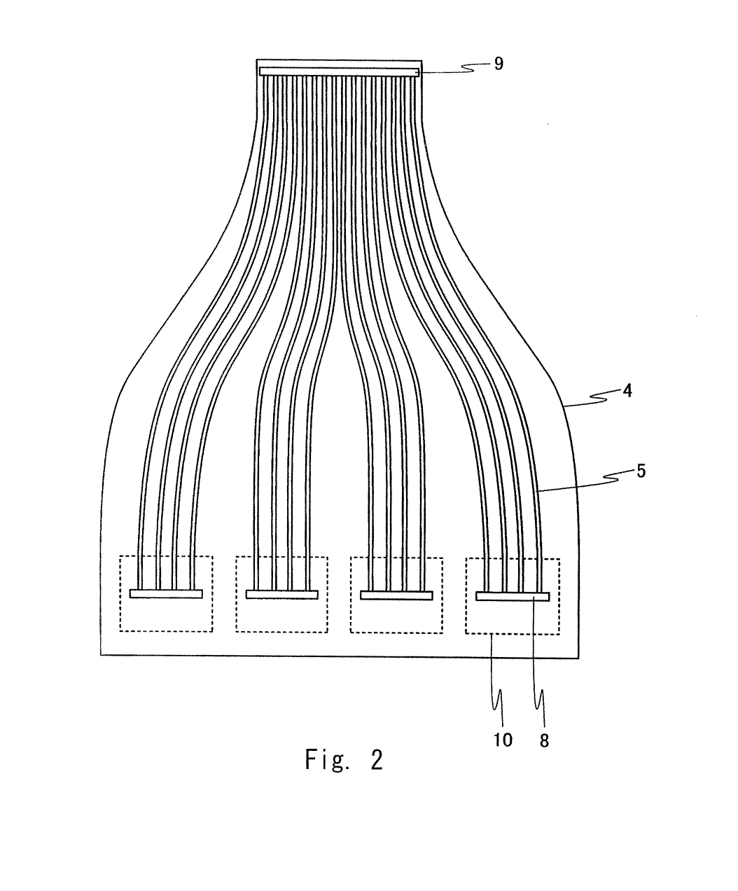

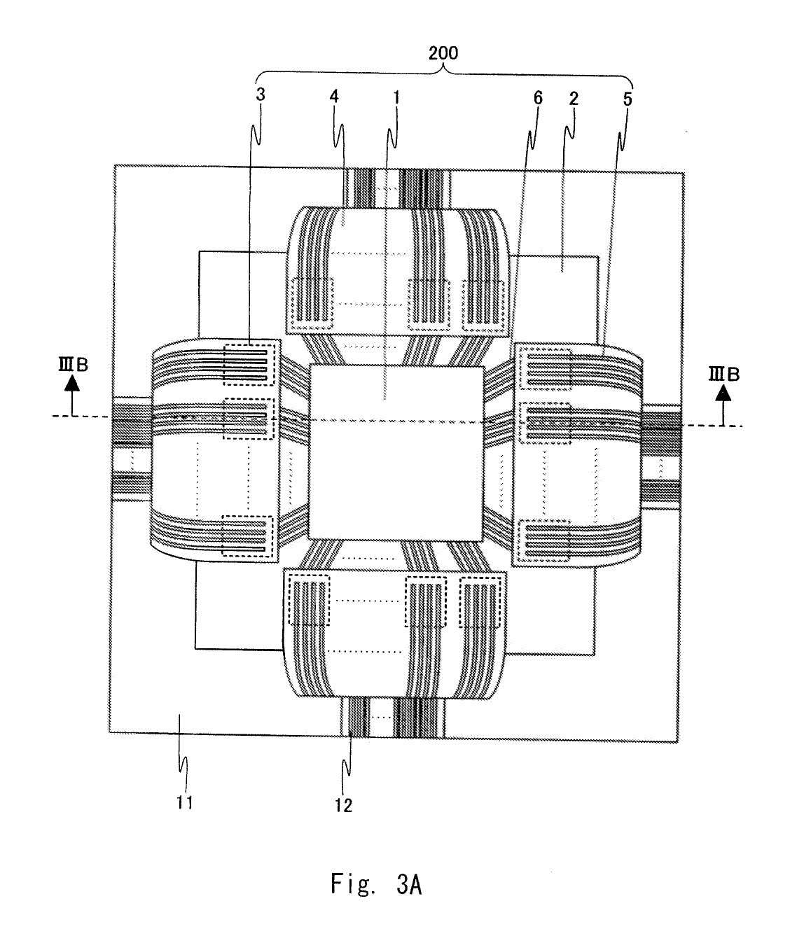

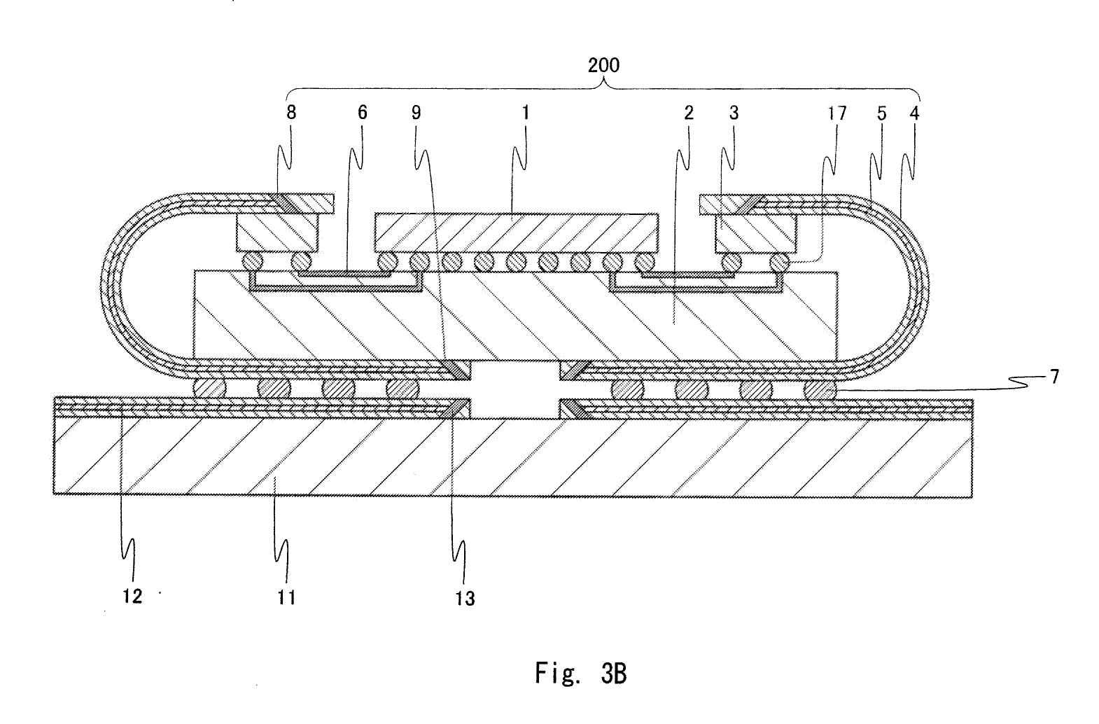

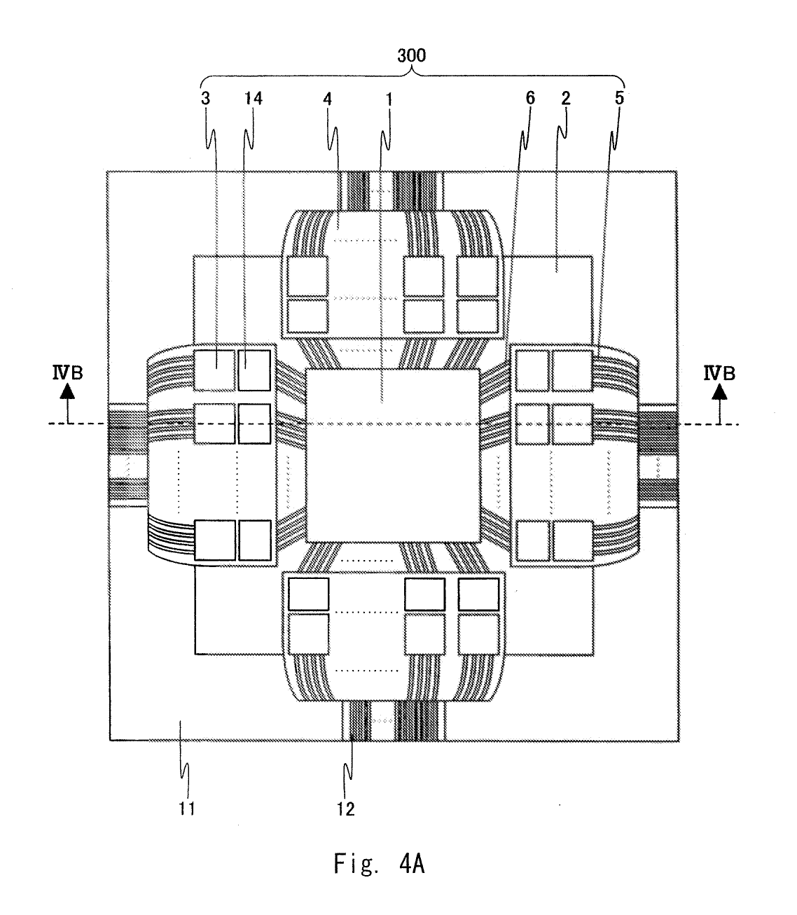

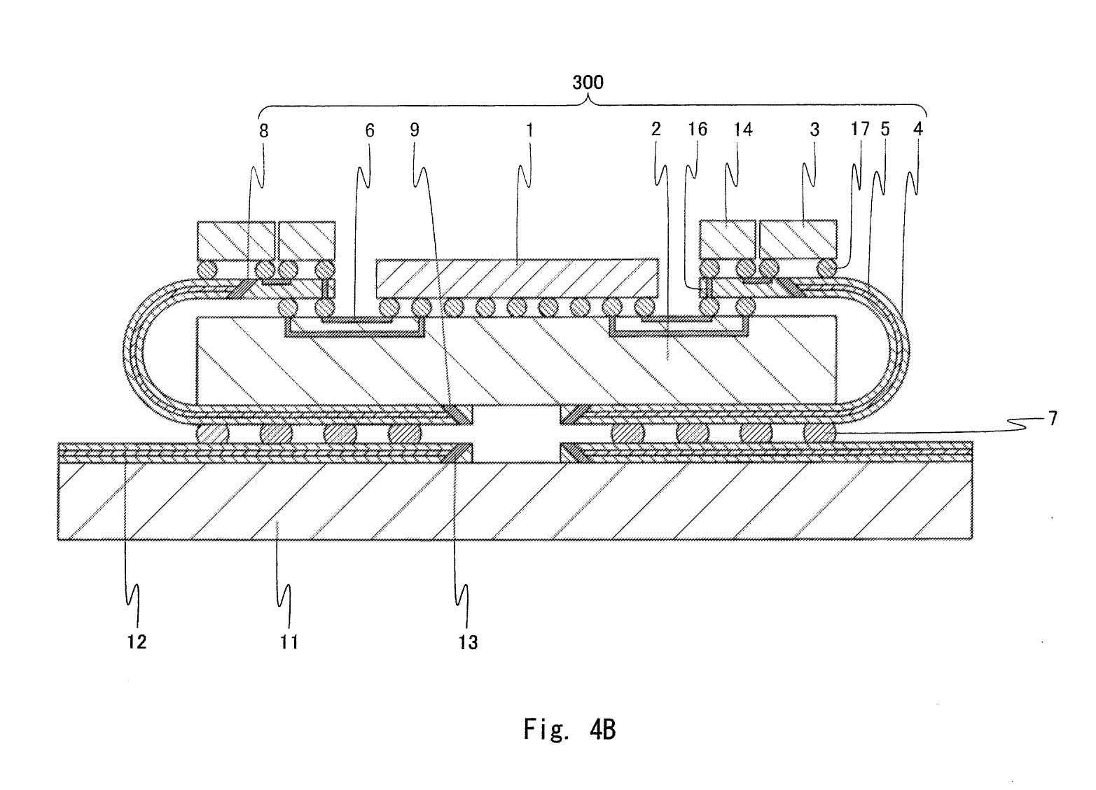

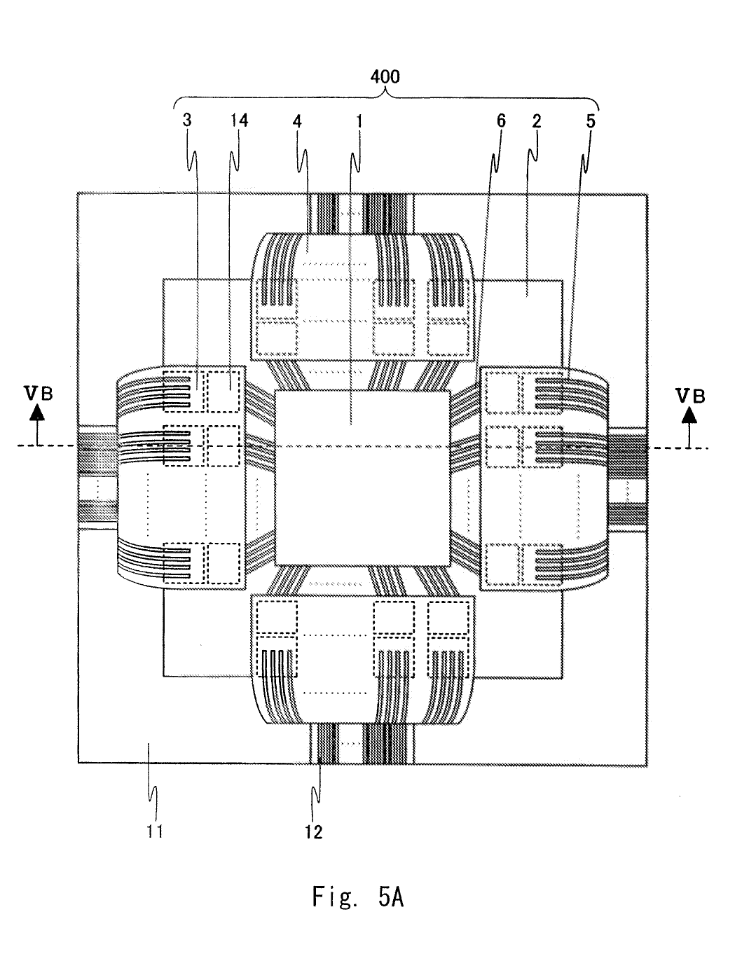

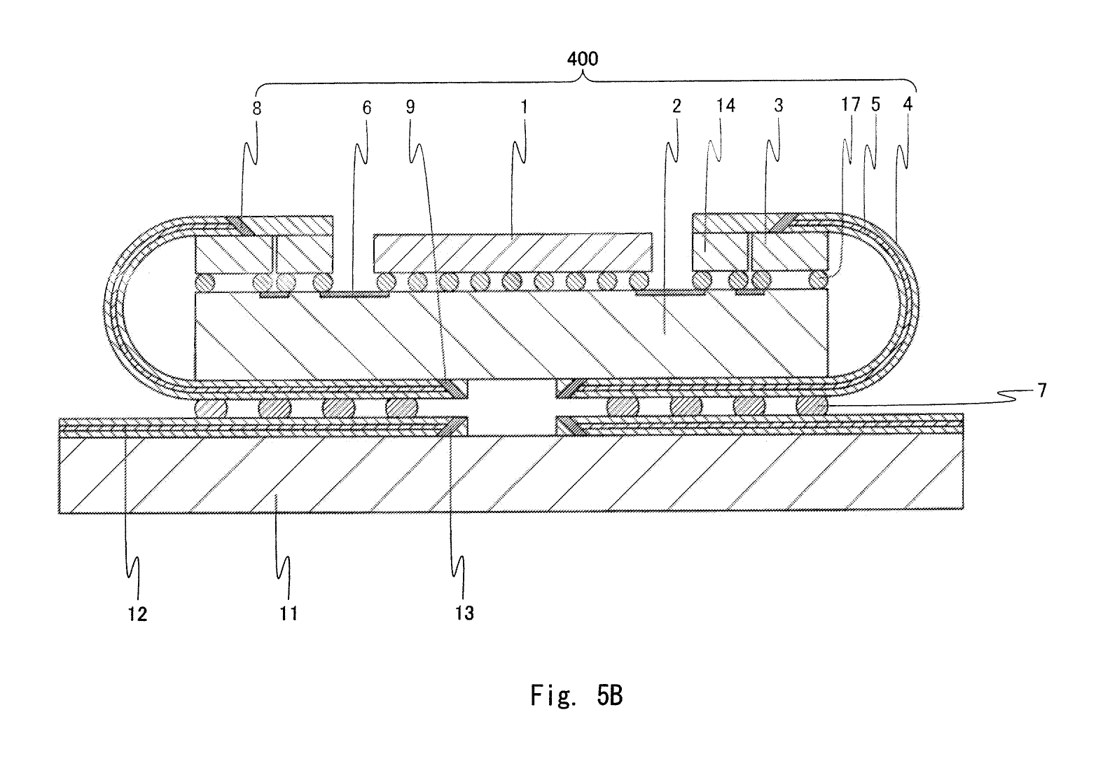

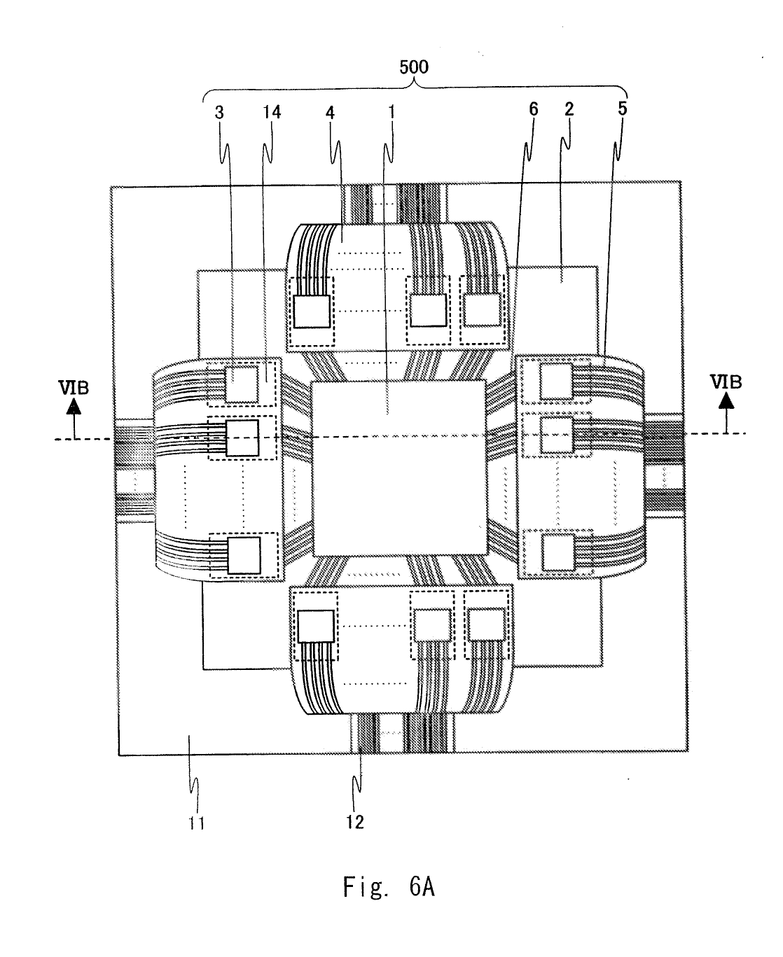

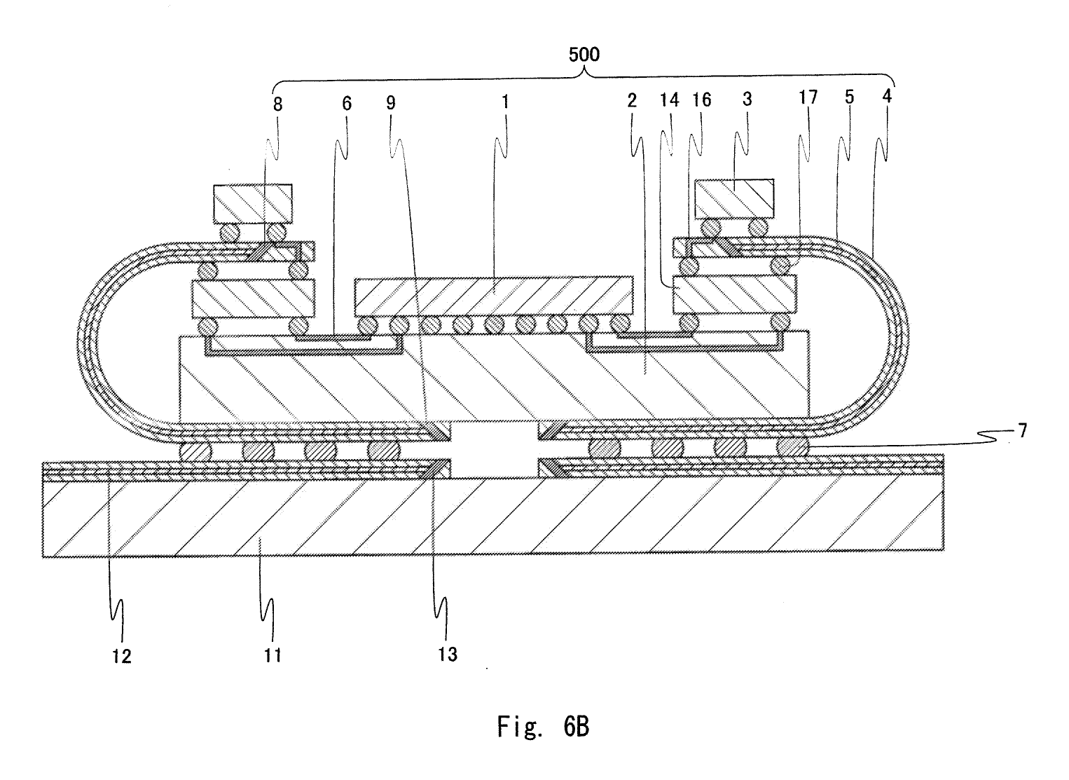

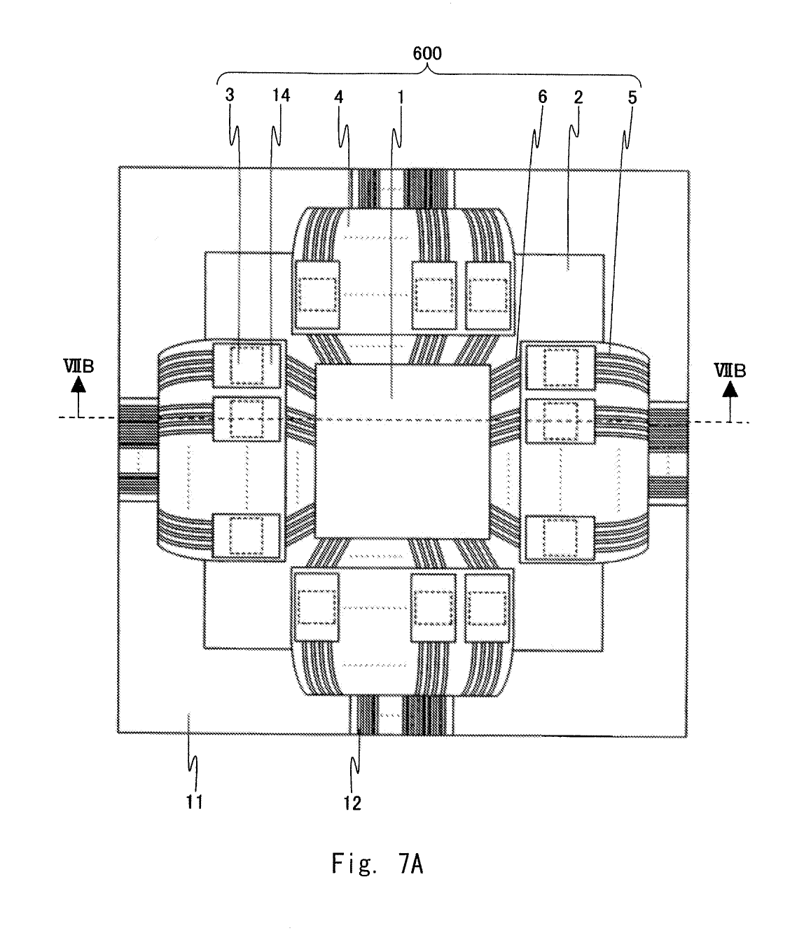

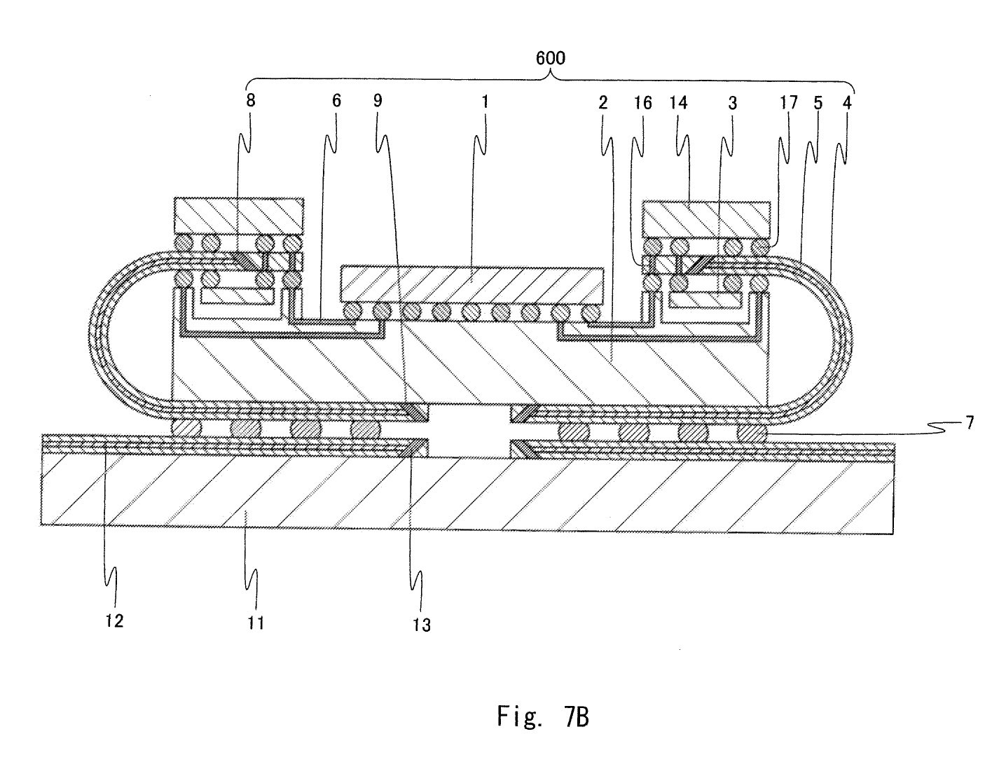

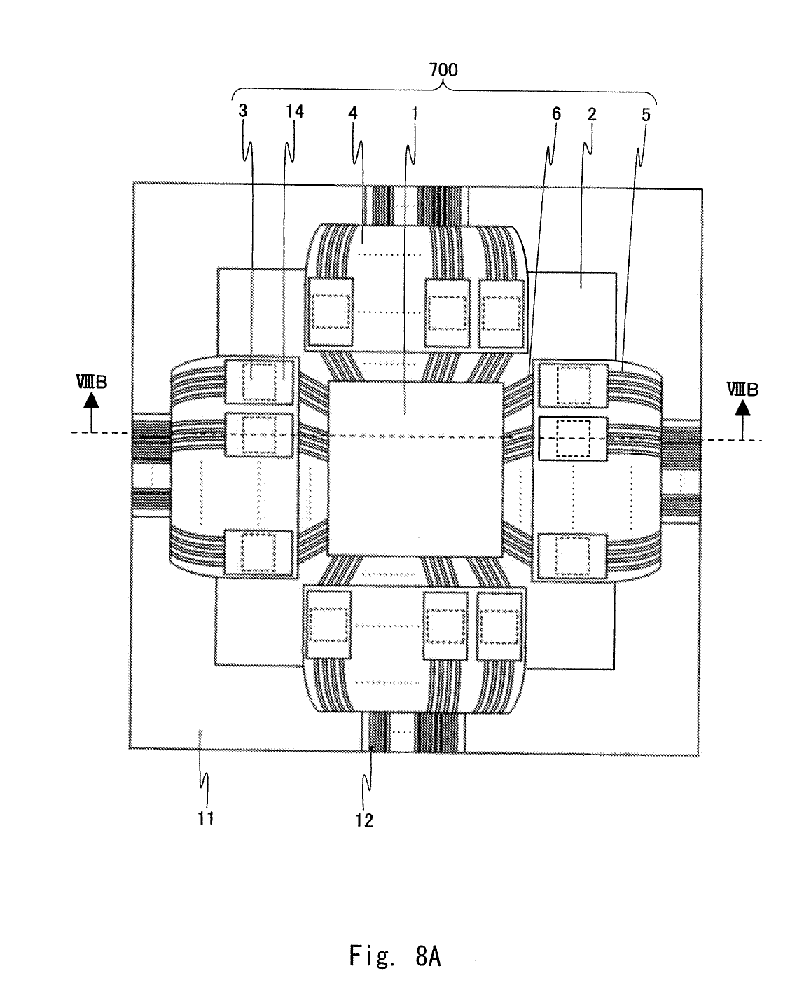

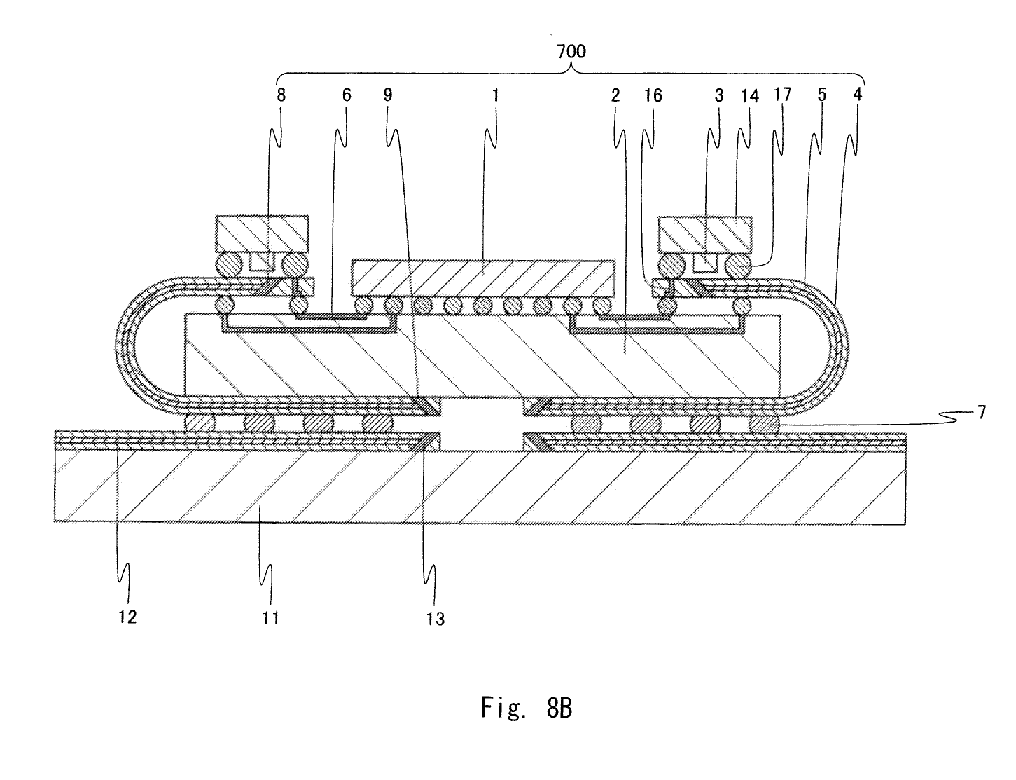

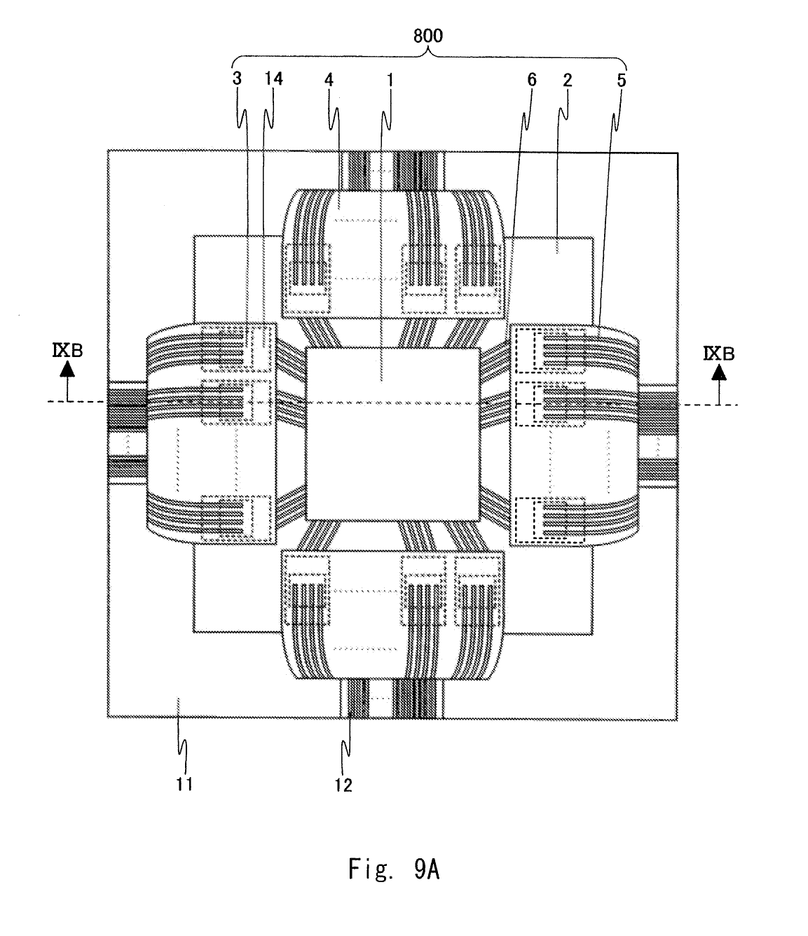

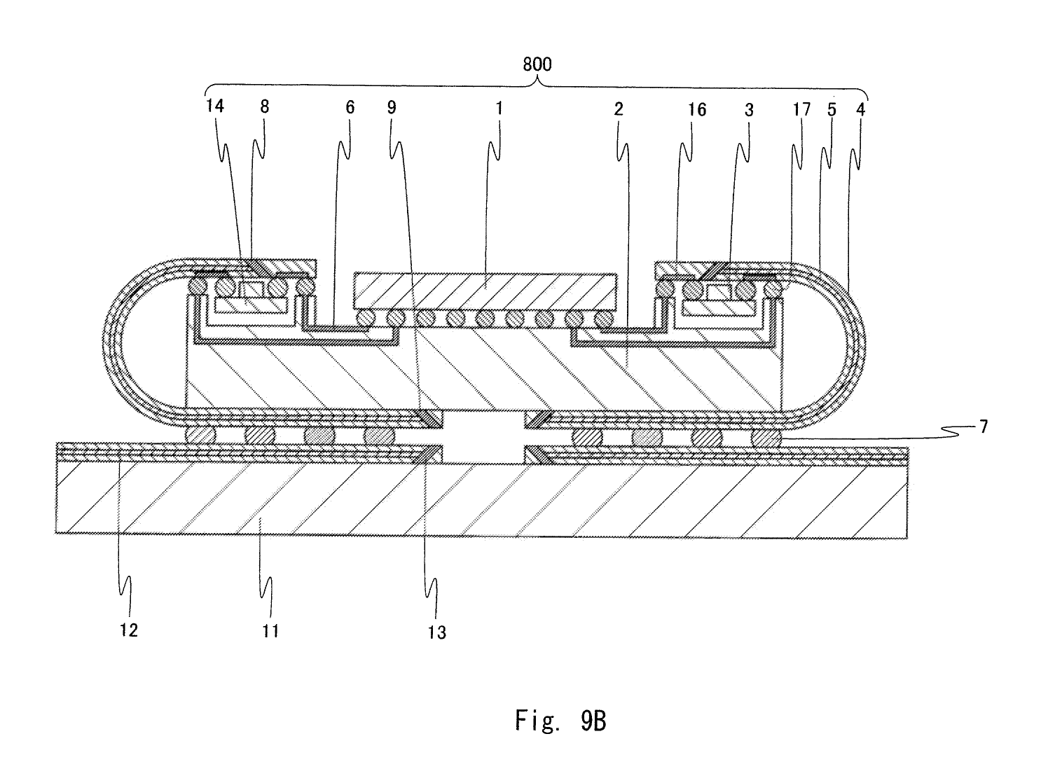

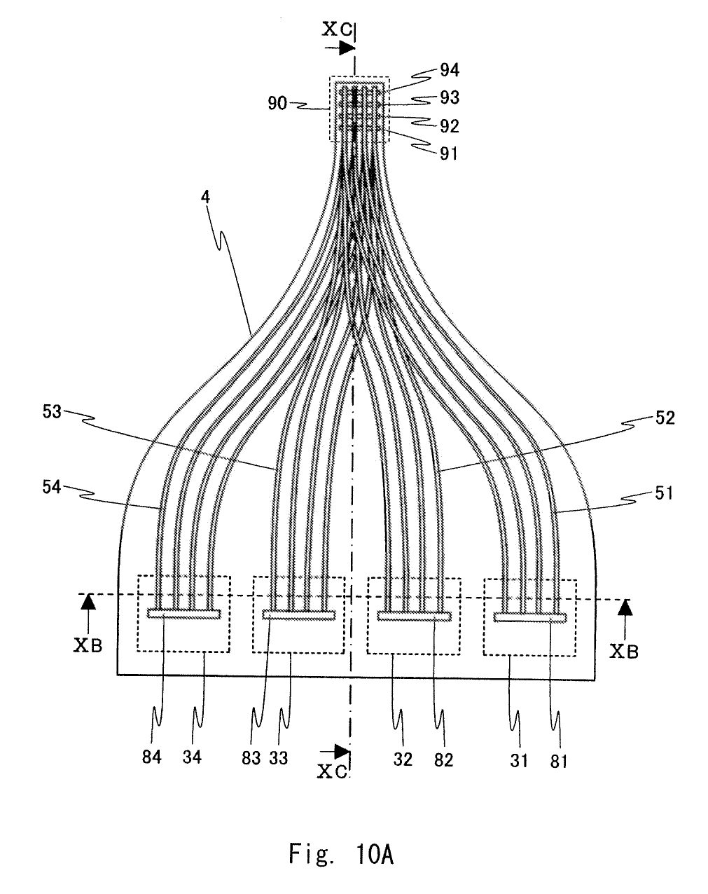

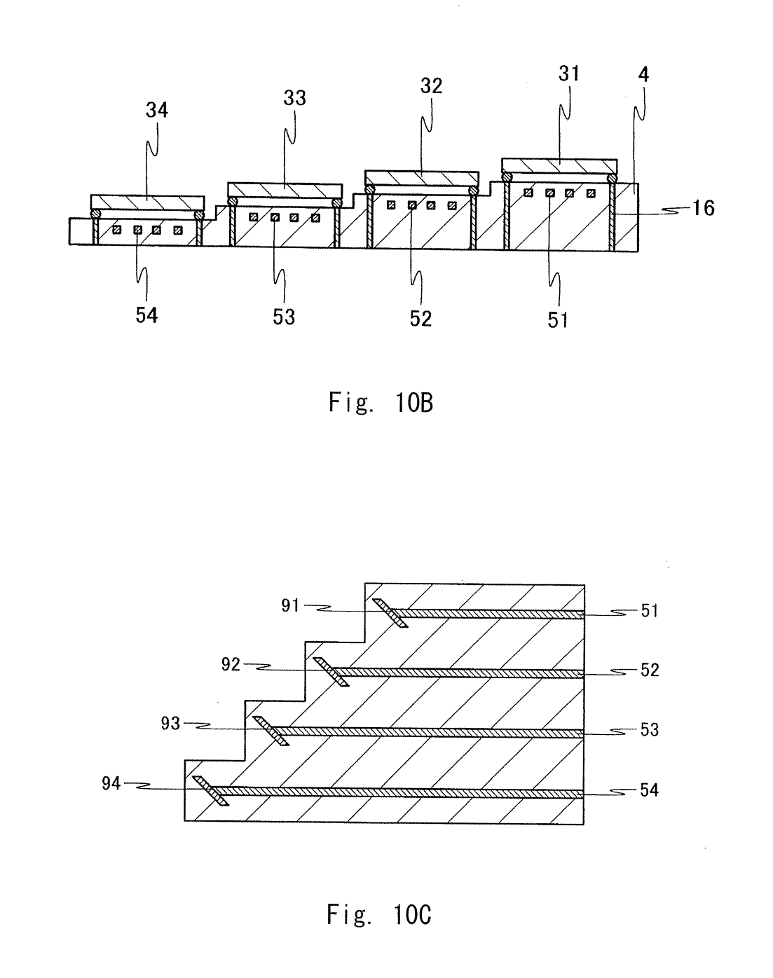

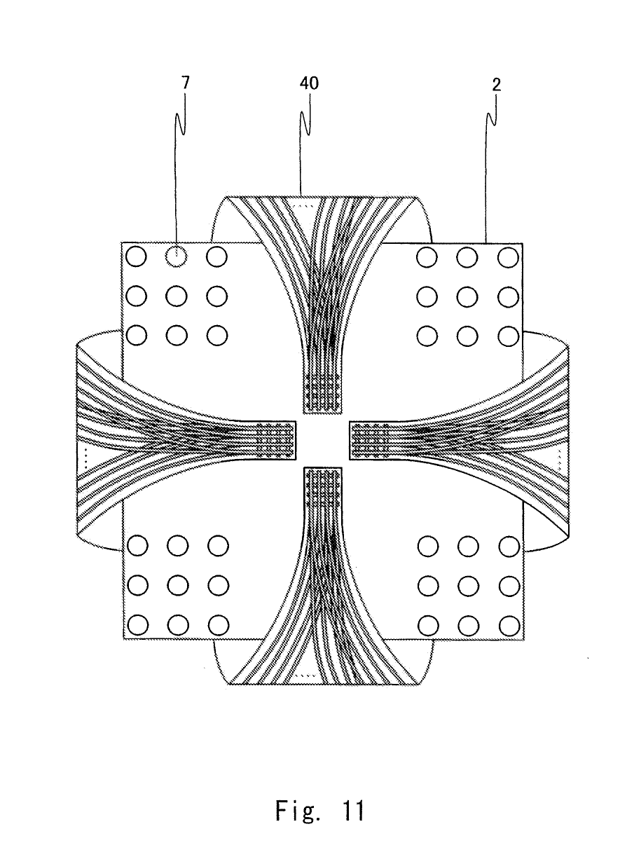

### BRIEF DESCRIPTION OF DRAWINGS

[FIG. 1A] A top view of a semiconductor device according to a first exemplary embodiment.

[FIG. 1B] A cross sectional view of the semiconductor device according to the first exemplary embodiment.

[FIG. 1C] A bottom view of a package of the semiconductor device according to the first exemplary embodiment.

[FIG. 2] A top view of a flexible optical waveguide substrate of the semiconductor device according to the first exemplary embodiment.

[FIG. 3A] A top view of a semiconductor device according to a second exemplary embodiment.

[FIG. 3B] A cross sectional view of the semiconductor device according to the second exemplary embodiment.

[FIG. 4A] A top view of a semiconductor device according to a third exemplary embodiment.

[FIG. 4B] A cross sectional view of the semiconductor device according to the third exemplary embodiment.

[FIG. 5A] A top view of a semiconductor device according to a fourth exemplary embodiment.

[FIG. 5B] A cross sectional view of the semiconductor device according to the fourth exemplary embodiment.

[FIG. 6A] A top view of a semiconductor device according to a fifth exemplary embodiment.

[FIG. 6B] A cross sectional view of the semiconductor device according to the fifth exemplary embodiment.

[FIG. 7A] A top view of a semiconductor device according to a sixth exemplary embodiment.

[FIG. 7B] A cross sectional view of the semiconductor device according to the sixth exemplary embodiment.

[FIG. 8A] A top view of a semiconductor device according to a seventh exemplary embodiment.

[FIG. 8B] A cross sectional view of the semiconductor device according to the seventh exemplary embodiment.

[FIG. 9A] A top view of a semiconductor device according to an eighth exemplary embodiment.

[FIG. 9B] A cross sectional view of the semiconductor device according to the eighth exemplary embodiment.

[FIG. 10A] A top view of a flexible optical waveguide substrate according to a ninth exemplary embodiment.

[FIG. 10B] A cross sectional view of the flexible optical waveguide substrate according to the ninth exemplary embodiment.

[FIG. 10C] A cross sectional view of an end part of the flexible optical waveguide substrate according to the ninth exemplary embodiment.

[FIG. 11] A bottom view of a package of a semiconductor device according to the ninth exemplary embodiment.

[FIG. 12A] A top view of an LSI package of a typical semiconductor device.

[FIG. 12B] A cross sectional view of the LSI package of the typical semiconductor device.

### DESCRIPTION OF EMBODIMENTS

### First Exemplary Embodiment

Hereinafter, with reference to the drawings, a first exemplary embodiment according to the present invention will be described. First, a structure of a semiconductor device according to the first exemplary embodiment will be described. FIG. 1A is a top view of a semiconductor device 100 according to the first exemplary embodiment. FIG. 1B is a cross sectional view of the semiconductor device 100 taken along the line IB-IB of FIG. 1A. Further, FIG. 1C is a bottom view of the semiconductor device 100 taken along the line IC-IC of FIG. 1B.

In the semiconductor device 100, an LSI chip 1 which is a semiconductor integrated circuit and a flexible optical waveguide substrate 4 which is a flexible optical waveguide are mounted on a package substrate 2. The LSI chip 1 is mounted on the package substrate 2 by flip-chip connection, for example, and is electrically and mechanically connected to an electrical line 6 formed in the package substrate 2. The flexible optical waveguide substrate 4 is made of resin or the like, and can be bent and stretched. The flexible optical waveguide substrate 4 is bent, one end of which being connected to the electrical line 6 on the upper surface of the package substrate 2, and the other end of which being connected to the bottom surface of the package substrate 2 (FIGS. 1A to 1C).

A plurality of optical waveguides 5 are formed in the flexible optical waveguide substrate 4. A first mirror 8 and a second mirror 9 are formed in each of the optical waveguides 5. Further, a pad (not shown) and an electrical line 16 penetrating the flexible optical waveguide substrate 4 are formed.

An optical element chip 3 is optically coupled to and mounted on the flexible optical waveguide substrate 4 by flip-chip connection, for example. The optical element chip 3 is electrically and mechanically connected to the electrical line 16. Further, the flexible optical waveguide substrate 4 is electrically and mechanically connected to the electrical line 6 of the package substrate 2 through bumps 17. Accordingly, the LSI chip 1 and the optical element chip 3 are electrically connected through the electrical line 6 and the electrical line 16 (FIG. 1B).

The package substrate 2 is mounted on a board 11. Solder balls 7 are formed on the bottom surface of the package substrate 2. The solder balls 7 electrically and mechanically connect the LSI chip 1 and the package substrate 2, each of the solder balls being used to supply power and for GND connection, for example. An electrical line (not shown) and an optical waveguide 12 are formed on the board 11. A third mirror 13 is formed at an end of the optical waveguide 12 (FIGS. 1A to 1C).

Next, the flexible optical waveguide substrate 4 will further be described. FIG. 2 is a top view of the flexible optical waveguide substrate 4. The flexible optical waveguide substrate 4 includes, as shown in FIG. 2, a plurality of optical waveguides 5, a first mirror 8, and a second mirror 9 formed therein. The first mirror 8 and the second mirror 9 are formed by a process method using a dicing blade, for example. The first mirror 8 is formed in a position 10 where the optical element chip is mounted. The position 10 where the optical element chip is mounted is a position where the optical element chip 3 is mounted. The second mirror 9 is formed at the end opposite to the position where the optical element chip is mounted.

The optical waveguides 5 are formed immediately below each optical element formed in the optical element chip 3. Four optical elements (not shown) are formed for each optical element chip 3 of the semiconductor device 100. Four optical waveguides 5 are formed immediately below the position 10 where the optical element chip is mounted. Typically, the optical elements of the optical element chip 3 are formed at regular pitches. In a commercially available optical element chip, optical elements are typically formed at the pitch of 250 μm. In the semiconductor device 100, the optical elements of the optical element chip 3 are formed at the typical pitch of 250 μm.

Further, when being mounted on the flexible optical waveguide substrate 4, the optical element chips 3 must be arranged with the intervals of about 500 μm. Thus, while the pitches of the optical waveguides 5 are 250 μm immediately below the optical element chips 3, the pitches of the optical waveguides 5 are wider than 250 μm between adjacent optical element chips 3. On the other hand, the pitches of the optical waveguides 5 may be narrower than 250 μm, e.g., 125 μm. In the semiconductor device 100, all or any of the optical waveguides 5 are formed in a curved shape to gradually narrow the pitches of the optical waveguides 5. In this way, the pitches of the optical waveguides 5 around the second mirror 9 are as narrow as 125 μm compared to the pitches of the optical waveguides 5 around the position 10 where the optical element chip is mounted. In summary, pitch changes of the optical waveguides 5 are achieved by forming all or any of the optical waveguides 5 in a curved shape.

Next, an operation of the semiconductor device 100 will be described. An electrical signal output from the LSI chip 1 is input to the optical element chip 3 through the electrical line 6 and the electrical line 16. The optical element chip 3 converts the received electrical signal into an optical signal to output the optical signal. The optical path of the optical signal output from the optical element chip 3 is changed by the first mirror 8, and the optical signal is input to the optical waveguide 5. The optical signal input to the optical waveguide 5 propagates through the optical waveguide 5 to the bottom surface side of the package substrate 2. The optical path of the optical signal that is propagated is changed by the second mirror 9 and the third mirror 13, and the optical signal is input to the optical waveguide 12 to propagate through the optical waveguide 12.

On the other hand, the optical path of the optical signal that is propagated through the optical waveguide 12 is changed by the third mirror 13 and the second mirror 9, and the optical signal is input to the optical waveguide 5. The optical signal that is input to the optical waveguide 5 propagates through the optical waveguide 5 to the upper surface side of the package substrate 2. The optical path of the optical signal that is propagated is changed by the first mirror 8, and the optical signal is input to the optical element chip 3. The optical element chip 3 converts the received optical signal into an electrical signal to output the electrical signal. The electrical signal that is output is input to the LSI chip 1 through the electrical line 16 and the electrical line 6.

Accordingly, the semiconductor device 100 achieves the drive by the optical input and output signals. Accordingly, the semiconductor device 100 enables optical signal transmission among LSI chips.

In summary, according to this structure, optical coupling of the optical elements and the optical waveguide formed in the board can be achieved without the use of optical vias or optical pins. Further, in the semiconductor device 100, the optical elements are optically coupled to the optical waveguides 5 formed in the flexible optical waveguide substrate 4. The optical waveguides 5 may be formed with excellent positional accuracy by lithography, which achieves higher positional accuracy than the method of forming the optical waveguides 5 using a drill like optical vias or optical pins. Accordingly, it is possible to improve the efficiency of optical coupling between the optical elements and the optical waveguides.

Further, according to this structure, the pitches of the optical waveguides 5 of the flexible optical waveguide substrate 4 are changed to be wide at the position 10 where the optical element chip is mounted and to be narrow on the side of the second mirror 9. Accordingly, the size of the area required to optically couple the optical waveguides 5 and the optical waveguides 12 can be made narrower than the case in which optical vias or optical pins are used. Thus, it is possible to reduce the influence of mis-alignment of the optical coupling caused by warpage due to stress or heat of the package substrate 2 and the board 11. Accordingly, in this structure, it is possible to further improve the efficiency of optical coupling.

Further, the pitches of the optical waveguides 12 may be made narrower than the case in which optical vias or optical pins are used. Thus, the area occupied by the optical waveguides on the board may be decreased, and the packaging density of the optical lines may be improved. Furthermore, the position where the optical waveguides 5 and the optical waveguides 12 are coupled may be arranged at any place. Thus, as shown in FIG. 1C, the position where the optical waveguides 5 and the optical waveguides 12 are coupled may be arranged at a position as close as possible to the center of the package substrate 2 instead of the position immediately below the optical element chip 3. As a result, the optical coupling position can be integrated to a narrower area. Accordingly, it is possible to further reduce the influence of mis-alignment of the optical coupling caused by warpage due to stress or heat of the package substrate 2 and the board 11, whereby it is possible to further improve the efficiency of optical coupling.

### Second Exemplary Embodiment

Next, a structure of a semiconductor device according to a second exemplary embodiment will be described. FIG. 3A is a top view of a semiconductor device 200 according to the second exemplary embodiment. FIG. 3B is a cross sectional view of the semiconductor device 200 taken along the line IIIB-IIIB of FIG. 3A. In the semiconductor device 200, an optical element chip 3 is directly mounted on a package substrate 2. A flexible optical waveguide substrate 4 is arranged on the optical element chip 3. Thus, the semiconductor device 200 need not provide an electrical line 16 as shown in FIG. 1 in the flexible optical waveguide substrate 4. A mirror 8 is arranged to change the optical path of an optical signal output upward to the optical element chip or input from above. Other structures are similar to those of the semiconductor device 100 according to the first exemplary embodiment; description will be omitted.

According to this structure, the similar function as that in the semiconductor device 100 according to the first exemplary embodiment may be achieved. Further, the bend radius of the flexible optical waveguide substrate 4 can be made larger than that of the semiconductor device 100. Accordingly, it is possible to reduce the loss in optical waveguides 5 compared to the semiconductor device 100.

### Third Exemplary Embodiment

Next, a structure of a semiconductor device according to a third exemplary embodiment will be described. FIG. 4A is a top view of a semiconductor device 300 according to the third exemplary embodiment. FIG. 4B is a cross sectional view of the semiconductor device 300 taken along the line IVB-IVB of FIG. 4A. In the semiconductor device 300, an optical element chip 3 and an electronic device chip 14 are mounted on a flexible optical waveguide substrate 4. In the semiconductor device 300, the electronic device chip 14 includes a driver and a receiver for driving optical elements. An electronic device or an electronic circuit integrated into the electronic device chip 14 may be any arbitrary one. For example, it may be a driver or a receiver for driving the optical elements, or may be a circuit for performing parallel/serial conversion. The optical element chip 3 and the electronic device chip 14 are electrically connected through an electrical line 16 formed in the flexible optical waveguide substrate 4. Other structures are similar to those in the semiconductor device 100 according to the first exemplary embodiment; description will be omitted.

According to this structure, the similar function as that in the semiconductor device 100 according to the first exemplary embodiment may be achieved. Further, it is possible to integrate a parallel/serial converter or a serial/parallel converter in the electronic device chip 14. Thus, a parallel electrical signal output from the LSI chip 1 may be serialized to be converted into an optical signal. Further, a serial optical signal may be converted into an electrical signal, then parallelized to be input to the LSI chip 1. As a result, the number of optical inputs and outputs may be reduced, thereby improving the density of the optical lines.

Further, the electronic device chip 14 manufactured by a process or material different from that in the LSI chip 1 may be used. For example, while the LSI chip 1 is typically manufactured by silicon complementary metal oxide semiconductor (CMOS), a driver or a receiver driving the optical elements may require high voltage. In such a case, a driver or a receiver made of compound semiconductor including SiGe is used instead of silicon CMOS. In summary, with the use of a receiver or a driver made of compound semiconductor including SiGe as the electronic device chip 14, it is possible to use the optical elements which require high voltage drive.

Further, an electronic device or an electronic circuit may be integrated in the optical element chip 3 in addition to the optical elements. Optical elements may be integrated in the electronic device chip 14 in addition to the electronic device or the electronic circuit.

### Fourth Exemplary Embodiment

Next, a structure of a semiconductor device according to a fourth exemplary embodiment will be described. FIG. 5A is a top view of a semiconductor device 400 according to the fourth exemplary embodiment. FIG. 5B is a cross sectional view of the semiconductor device 400 taken along the line VB-VB of FIG. 5A. In the semiconductor device 400, an optical element chip 3 and an electronic device chip 14 are directly mounted on a package substrate 2. The optical element chip 3 and the electronic device chip 14 are electrically connected through an electrical line 6. A flexible optical waveguide substrate 4 is arranged on the optical element chip 3. Accordingly, the semiconductor device 200 need not provide an electrical line 16 as shown in FIG. 1 in the flexible optical waveguide substrate 4. A mirror 8 is arranged to change the optical path of an optical signal output upward to the optical element chip or input from above. Other structures are similar to those in the semiconductor device 100 according to the first exemplary embodiment; description thereof will be omitted.

According to this structure, the similar function as that in the semiconductor device 300 according to the third exemplary embodiment may be achieved. Further, the bend radius of the flexible optical waveguide substrate 4 can be made larger than that of the semiconductor device 300. Accordingly, the loss in the optical waveguides 5 can be reduced compared to the semiconductor device 300.

### Fifth Exemplary Embodiment

Next, a structure of a semiconductor device according to a fifth exemplary embodiment will be described. FIG. 6A is a top view of a semiconductor device 500 according to the fifth exemplary embodiment. FIG. 6B is a cross sectional view of the semiconductor device 500 taken along the line VIB-VIB of FIG. 6A. In the semiconductor device 500, an electronic device chip 14 is directly mounted on a package substrate 2. A flexible optical waveguide substrate 4 is arranged above the electronic device chip 14, and an optical element chip 3 is arranged above the flexible optical waveguide substrate 4. The optical element chip 3 and the electronic device chip 14 are electrically connected through an electrical line 16 formed to penetrate the flexible optical waveguide substrate 4. Further, an electrical pad (not shown) is formed on both surfaces of the electronic device chip 14, and a through electrode (not shown) penetrating the chip is formed between the electrical pads. Other structures are similar to those in the semiconductor device 100 according to the first exemplary embodiment; description will be omitted.

According to this structure, it is possible to achieve the similar function as that of the semiconductor device 300 according to the third exemplary embodiment. Further, the bend radius of the flexible optical waveguide substrate 4 can be made larger compared to the semiconductor device 300, whereby the loss of the optical waveguides 5 can be reduced. Further, since the optical element chip 3 and the electronic device chip 14 are arranged so as to be overlapped with each other in the vertical direction, the area occupied by the optical element chip 3 and the electronic device chip 14 can be made narrower than that of the semiconductor device 300. As a result, the packaging density can be improved.

### Sixth Exemplary Embodiment

Next, a structure of a semiconductor device according to a sixth exemplary embodiment will be described. FIG. 7A is a top view of a semiconductor device 600 according to the sixth exemplary embodiment. FIG. 7B is a cross sectional view of the semiconductor device 600 taken along the line VIIB-VIIB of FIG. 7A. In the semiconductor device 600, an electronic device chip 14 is arranged above a flexible optical waveguide substrate 4. An optical element chip 3 is arranged below the flexible optical waveguide substrate 4. The electronic device chip 14, the optical element chip 3, and a package substrate 2 are electrically connected through an electrical line 16 formed to penetrate the flexible optical waveguide substrate 4. In the electronic device chip 14, a through electrode is not formed. Other structures are similar to those in the semiconductor device 100 according to the first exemplary embodiment; description thereof will be omitted.

According to this structure, the similar function as that in the semiconductor device 500 according to the fifth exemplary embodiment may be achieved. While a through electrode need to be provided in the electronic device chip 14 in the semiconductor device 500, the through electrode is not required in this structure. Accordingly, this structure has an advantage that it is possible to reduce costs required to manufacture the electronic device chip 14.

### Seventh Exemplary Embodiment

Next, a structure of a semiconductor device according to a seventh exemplary embodiment will be described. FIG. 8A is a top view of a semiconductor device 700 according to the seventh exemplary embodiment. FIG. 8B is a cross sectional view of the semiconductor device 700 taken along the line VIIIB-VIIIB of FIG. 8A. In the semiconductor device 700, an electronic device chip 14 and an optical element chip 3 are mounted above a flexible optical waveguide substrate 4 so as to be overlapped with each other in the vertical direction. The electronic device chip 14 and a package substrate 2 are electrically connected through an electrical line 16 formed to penetrate a flexible optical waveguide substrate 4. Other structures are similar to those in the semiconductor device 100 according to the first exemplary embodiment; description thereof will be omitted.

According to this structure, the similar function as that in the semiconductor device 500 according to the fifth exemplary embodiment may be achieved. Further, in this structure, the optical element chip 3 and the electronic device chip 14 are directly connected so as to be overlapped with each other in the vertical direction. Accordingly, it is possible to further reduce degradation of a high-speed electrical signal transmitted between the optical element chip 3 and the electronic device chip 14 compared to the form of connecting the optical element chip 3 and the electronic device chip 14 through the flexible optical waveguide substrate 4 as in the semiconductor device 500.

### Eighth Exemplary Embodiment

Next, a structure of a semiconductor device according to an eighth exemplary embodiment will be described. FIG. 9A is a top view of a semiconductor device 800 according to the eighth exemplary embodiment. FIG. 9B is a cross sectional view of the semiconductor device 800 taken along the line IXB-IXB of FIG. 9A. In the semiconductor device 800, an electronic device chip 14 and an optical element chip 3 are mounted below a flexible optical waveguide substrate 4 so as to be overlapped with each other in the vertical direction. The electronic device chip 14 and a package substrate 2 are electrically connected through an electrical line 16 formed in the flexible optical waveguide substrate 4. Other structures are similar to those in the semiconductor device 700 according to the seventh exemplary embodiment; description thereof will be omitted.

According to this structure, the similar function as that in the semiconductor device 700 according to the seventh exemplary embodiment may be achieved. Further, it is possible to increase the bend radius of the flexible optical waveguide substrate 4 compared to the semiconductor device 700. Accordingly, it is possible to further reduce the loss in the optical waveguides 5 compared to the semiconductor device 700.

### Ninth Exemplary Embodiment

Next, a ninth exemplary embodiment will be described. In the ninth exemplary embodiment, the structure of the flexible optical waveguide substrate in the above first to eighth exemplary embodiments is changed. Accordingly, the structures of the ninth exemplary embodiment and those of the first to eighth exemplary embodiments are similar except the structure of the flexible optical waveguide substrate. Thus, in the following description, a flexible optical waveguide substrate 40 according to the ninth exemplary embodiment will be described. FIG. 10A is a top view of the flexible optical waveguide substrate 40 according to the ninth exemplary embodiment. FIG. 10B is a cross sectional view of the flexible optical waveguide substrate 40 taken along the line XB-XB of FIG. 10A. FIG. 10C is a cross sectional view of an end part 90 taken along the line XC-XC of FIG. 10A. In the flexible optical waveguide substrate 40, optical waveguides are formed in multiple layers compared to the flexible optical waveguide substrate 4 shown in FIG. 2. The ninth exemplary embodiment will be described taking a case in which four-layer optical waveguides 51-54 are formed as an example.

In the ninth exemplary embodiment, four optical element chips 31-34 are mounted on the flexible optical waveguide substrate 40, for example. The positions where the optical element chips 31-34 are mounted are indicated by dotted lines. The optical element chips 31-34 have four optical elements formed therein. In the flexible optical waveguide substrate 40, four bundles of optical waveguides 51-54, each bundle including four optical waveguides are formed. First mirrors 81-84 are formed at ends of the optical waveguides 51-54 where the optical element chip 31 is mounted (FIG. 10A). In summary, the optical element chips 31-34 are arranged to be optically coupled to the optical waveguides 51-54, respectively.

The optical waveguides 51 are formed in the uppermost layer, and the optical waveguides 52-54 are formed in order below the optical waveguides 51 (FIGS. 10B and 10C). One effective measure to improve optical coupling efficiency of the optical elements and the optical waveguides is to decrease the distance between the optical elements and the optical waveguides. Thus, steps are provided in the flexible optical waveguide substrate 40. Accordingly, each optical waveguide and the optical elements optically coupled to the optical waveguides may be provided as close as possible with each other (FIG. 10B). Further, in the end part 90, second mirrors 91-94 to change the optical path of the transmitting light are formed at the end of the optical waveguides 51-54, respectively (FIG. 10C).

The pitches of the optical waveguides 51-54 are gradually made narrower from the optical element chips 31-34 through a curved part toward the end part 90. At the same time, the optical waveguides 51-54 are overlapped in layers in the vertical direction, and have the layered structure at the end part 90 as shown in FIG. 10C. Further, at the end part 90, steps are formed in the flexible optical waveguide substrate 40, and the thickness of the flexible optical waveguide substrate 40 is gradually decreased from the mirror 91 toward the mirror 94. In short, according to this structure, the width on the side of the end part 90 of the flexible optical waveguide substrate 40 may be made narrower than that of the flexible optical waveguide substrate 4.

While the flexible optical waveguide substrate 4 as shown in FIG. 2 has been used in the first to eighth exemplary embodiments stated above, the flexible optical waveguide substrate 40 according to the ninth exemplary embodiment may be used instead. FIG. 12 is a bottom view of the semiconductor device when the flexible optical waveguide substrate 40 is used in the first to eighth exemplary embodiments. As shown in FIG. 12, with the use of the flexible optical waveguide substrate 40, it is possible to narrow the area where the second mirror is formed, i.e., a width of a range of the position optically coupled to the board 11. Thus, the position of the optical coupling with the board 11 may be arranged closer to the center of the package substrate 2. Thus, the influence of mis-alignment of the optical coupling caused by warpage due to stress or heat of the package substrate 2 and the board 11 may further be reduced compared to the first to eighth exemplary embodiments. Accordingly, the efficiency of optical coupling may further be improved, and the density of the optical lines of the board 11 may further be improved. When the flexible optical waveguide substrate 40 is used, optical waveguides 12 of the board 11 are also formed of a plurality of optical waveguide layers.

### Other Exemplary Embodiments

Note that the present invention is not limited to the exemplary embodiments stated above, but may be changed as appropriate without departing from the spirit of the present invention. For example, while optical waveguides of the flexible optical waveguide substrate and optical waveguides of the board are optically coupled by mirrors in the exemplary embodiments described above, light collecting means such as a lens may be arranged between the mirror of the board and the second mirror of the flexible optical waveguide substrate in order to improve the coupling efficiency. Accordingly, it is possible to collect the light output from the flexible optical waveguide substrate to input the light into the waveguides of the board, or to collect the light output from the board to input the light into the waveguides of the flexible optical waveguide substrate with high efficiency. Further, the light conversion means is not limited to mirrors, but may be any other means including grating couplers or connectors.

While the package substrate and the board are connected via solder balls, any connection method including sockets may be used instead. Further, while the optical waveguides are formed on the surface of the board, the optical waveguides may be formed inside the board.

The number of optical elements formed in the optical element chip may be any number other than four. Further, the number of optical elements formed in each optical element chip 3 may be varied. Furthermore, any electronic device or an electric circuit (e.g., a driver or a receiver for driving the optical elements) may be integrated and formed in the optical element chip 3 in addition to the optical elements.

The number of LSI chips mounted on the package substrate is not limited to one but may be a plural number. Further, while the LSI chip and the optical element chip are mounted by flip-chip connection, they may be mounted by any mounting method including wire bonding or tape automated bonding (TAB), for example.

The number of flexible optical waveguide substrates may be any number other than four. Further, the flexible optical waveguide substrate may be connected to the package substrate 2 by other methods than the method using bumps. Further, the first to third mirrors may be formed by any process method including a laser process instead of the process by a dicing blade.

In the ninth exemplary embodiment, four-layer optical waveguides are formed in the flexible optical waveguide substrate 40. Note that the number of layers of the optical waveguides formed in the flexible optical waveguide substrate 40 may be any number other than four. Further, the number of optical element chips 3 mounted on the flexible optical waveguide substrate 40 may be any number other than four. In the flexible optical waveguide substrate 40, the optical element chips 31-34 are configured to be optically coupled to the optical waveguides 51-54, respectively. However, the optical waveguides optically coupled to the optical element chips may be variously combined. Further, while the flexible optical waveguide substrate 4 becomes gradually thinner from the optical element chip 31 toward the optical element chip 34 in the flexible optical waveguide substrate 40, it is not necessary that steps are provided in stages, or the steps may not be formed. Further, each optical waveguide formed in multiple layers may not be overlapped in the end part 90 or may be partially overlapped. While the thickness of the flexible optical waveguide substrate 40 becomes gradually thinner from the mirror 91 toward the mirror 94 in the end part 90, the steps may not be provided in stages, or the steps may not be formed.

This application claims the benefit of priority, and incorporates herein by reference in its entirety, the following Japanese Patent Application No. 2009-253117 filed on Nov. 4, 2009.

### INDUSTRIAL APPLICABILITY

A technique according to the present invention may be used for optical interconnection among semiconductor elements including LSIs used in device including servers, routers, and computers.

### REFERENCE SIGNS LIST

1 LSI CHIP
2 PACKAGE SUBSTRATE
3 OPTICAL ELEMENT CHIP
4 FLEXIBLE OPTICAL WAVEGUIDE SUBSTRATE
5 OPTICAL WAVEGUIDE
6 ELECTRICAL LINE
7 SOLDER BALL
8 FIRST MIRROR
9 SECOND MIRROR
10 POSITION WHERE OPTICAL ELEMENT CHIP IS MOUNTED
11 BOARD
12 OPTICAL WAVEGUIDE
13 THIRD MIRROR
14 ELECTRONIC DEVICE CHIP
16 ELECTRICAL LINE
17 BUMP
31-34 OPTICAL ELEMENT CHIP
40 FLEXIBLE OPTICAL WAVEGUIDE SUBSTRATE
51-54 OPTICAL WAVEGUIDE
61 LSI CHIP
62 PACKAGE SUBSTRATE
63 OPTICAL ELEMENT CHIP
64 OPTICAL VIA
66 ELECTRICAL LINE
67 SOLDER BALL
71 BOARD
72 OPTICAL WAVEGUIDE
73 MIRROR
77 BUMP
81-84 FIRST MIRROR
90 END PART
91-94 SECOND MIRROR
100, 200, 300, 400, 500, 600, 700, 800 SEMICONDUCTOR DEVICE
1000 LSI PACKAGE

1. A semiconductor device comprising:
a semiconductor integrated circuit;
a package substrate on which the semiconductor integrated circuit is mounted;
an optical element that is arranged on a first surface of the package substrate and electrically connected to the semiconductor integrated circuit through the package substrate; and
a flexible optical waveguide that has one end optically coupled to the optical element and another end arranged on a side of a second surface of the package substrate opposed to the first surface, the flexible optical waveguide having flexibility.

2. The semiconductor device according to claim 1, wherein the flexible optical waveguide comprises:
a flexible substrate that has flexibility;
a plurality of optical waveguides that are formed on the flexible substrate; and
an optical path convertor that converts a direction of light propagating through the plurality of optical waveguides.

3. The semiconductor device according to claim 2, wherein the optical path convertor is formed on one end or both ends of each of the plurality of optical waveguides.

4. The semiconductor device according to claim 3, wherein the optical path convertor is formed on one end or both ends of a part of the optical waveguides among the plurality of optical waveguides.

5. The semiconductor device according to claim 2, wherein the optical path convertor comprises a reflector.

6. The semiconductor device according to claim 2, wherein
each of the plurality of optical waveguides comprises a curved part, and
a gap between the optical waveguides including the curved parts in one end optically coupled to the optical element is larger than a gap in another end.

7. The semiconductor device according to claim 2, wherein
a part of the optical waveguides among the plurality of optical waveguides each has a curved part, and
a gap between the part of optical waveguides including the curved parts in one end optically coupled to the optical element is larger than a gap in another end.

8. The semiconductor device according to claim 2, wherein the plurality of optical waveguides are formed to be divided into a plurality of optical waveguide layers that are layered.

9. The semiconductor device according to claim 8, wherein, in one end of the flexible optical waveguide arranged on a side of the second surface of the package substrate opposed to the first surface, the optical waveguide layers are overlapped with each other, so that the plurality of optical waveguides are formed to be partially overlapped with each other.

10. The semiconductor device according to claim 2, wherein the flexible optical waveguide further comprises a first light collector that collects light whose optical path is changed by the optical path convertor and emitted from the flexible optical waveguide.

11. The semiconductor device according to claim 10, wherein the first light collector comprises a lens.

12. The semiconductor device according to claim 2, wherein the flexible optical waveguide further comprises a second light collector that collects light input to the optical path convertor of the flexible optical waveguide from outside of the flexible optical waveguide.

13. The semiconductor device according to claim 12, wherein the second light collector comprises a lens.

14. The semiconductor device according to claim 1, further comprising a semiconductor element arranged on the first surface and driving the optical element.

15. The semiconductor device according to claim 14, wherein the optical element is arranged between the flexible optical waveguide and the package substrate.

16. The semiconductor device according to claim 15, wherein the semiconductor element is arranged between the flexible optical waveguide and the package substrate.

17. The semiconductor device according to claim 14, wherein
the flexible optical waveguide further comprises an electrical line formed in the flexible optical waveguide, and
the electrical line comprises a through line for penetrating the flexible optical waveguide.

18. The semiconductor device according to claim 17, wherein
the flexible optical waveguide is arranged between the optical element and the package substrate, and
the optical element is electrically connected to the package substrate via the through line.

19. The semiconductor device according to claim 18, wherein
the semiconductor element is arranged to be opposed to the first surface of the package substrate through the flexible optical waveguide, and
the semiconductor element is electrically connected to the optical element through the electrical line.

20. The semiconductor device according to claim 18, wherein
the semiconductor element is arranged between the flexible optical waveguide and the package substrate, and
the semiconductor element is electrically connected to the optical element through the electrical line.

21. The semiconductor device according to claim 17, wherein
the flexible optical waveguide is arranged between the optical element and the package substrate,
the semiconductor element is arranged between the flexible optical waveguide and the package substrate, and
the optical element is electrically connected to the semiconductor element through the through electrode.

22. The semiconductor device according to claim 17, wherein
the flexible optical waveguide is electrically connected to the package substrate,
the optical element is arranged between the flexible optical waveguide and the package substrate, and
the semiconductor element is arranged to be opposed to the first surface of the package substrate through the flexible optical waveguide, and is electrically connected to the package and the optical element via the through line.

23. The semiconductor device according to claim 17, wherein
the flexible optical waveguide is arranged between the semiconductor element and the package substrate, and is electrically connected to the package substrate,
the optical element is arranged between the flexible optical waveguide and the semiconductor element so as to be integrated with the semiconductor element, and
the semiconductor element is electrically connected to the package substrate through the through electrode.

24. The semiconductor device according to claim 17, wherein
the flexible optical waveguide is electrically connected to the package substrate,
the semiconductor element is arranged between the flexible optical waveguide and the package substrate, and is electrically connected to the package substrate through the electrical line, and
the optical element is arranged between the flexible optical waveguide and the semiconductor element so as to be integrated with the semiconductor element.

25. A method of manufacturing a semiconductor device, comprising:
mounting a semiconductor integrated circuit on a package substrate;
arranging an optical element on a first surface of the package substrate to electrically connect the optical element to the semiconductor integrated circuit through the package substrate; and
optically coupling the optical element and one end of a flexible optical waveguide having flexibility, and arranging another end of the flexible optical waveguide on a side of a second surface of the package substrate opposed to the first surface.

26. The semiconductor device according to claim 1, wherein the flexible optical waveguide comprises:
a flexible substrate that has flexibility;
a plurality of optical waveguides that are formed on the flexible substrate; and
optical path conversion means for converting a direction of light propagating through the plurality of optical waveguides.

27. The semiconductor device according to claim 26, wherein the optical path conversion means is formed on one end or both ends of each of the plurality of optical waveguides.

28. The semiconductor device according to claim 27, wherein the optical path conversion means is formed on one end or both ends of a part of the optical waveguides among the plurality of optical waveguides.

29. The semiconductor device according to claims 26, wherein the optical path conversion means comprises a reflector.

30. The semiconductor device according to claim 26, wherein the flexible optical waveguide further comprises first light collecting means for collecting light whose optical path is changed by the optical path conversion means and emitted from the flexible optical waveguide.

31. The semiconductor device according to claim 30, wherein the first light collecting means comprises a lens.

32. The semiconductor device according to claim 26, wherein the flexible optical waveguide further comprises second light collecting means for collecting light input to the optical path conversion means of the flexible optical waveguide from outside of the flexible optical waveguide.

33. The semiconductor device according to claim 32, wherein the second light collecting means comprises a lens.
